(19) United States
(12) Patent Application Publication
(10) Pub. No.: US 2026/0271745 A1
(43) Pub. Date: Sep. 10, 2026

(54) SEMICONDUCTOR DEVICE PACKAGES WITH REDUCED FORM FACTOR

(71) Applicant: SEMICONDUCTOR COMPONENTS INDUSTRIES, LLC, Scottsdale, AZ (US)

(72) Inventors: Heejo CHI, Yeoju-si (KR); Keunhyuk LEE, Suzhou (CN); Jonghwan BAEK, Seoul (KR); Seungwon IM, Bucheon (KR); Bosung WON, Seoul (KR); DingHao WU, Suzhou (CN); Jie CHANG, Suzhou (CN); Cheng HU, Suzhou (CN); AnAn XING, Suzhou (CN); XiaoYing YUAN, Suzhou (CN)

(73) Assignee: SEMICONDUCTOR COMPONENTS INDUSTRIES, LLC, Scottsdale, AZ (US)

(21) Appl. No.: 19/073,954

(22) Filed: Mar. 7, 2025

(51) Int. Cl. H01L 23/495; H01L 23/29

(52) U.S. Cl. CPC H10W 70/465; H10W 70/415; H10W 70/429; H10W 70/457; H10W 74/47

(57) ABSTRACT

In a general aspect, a semiconductor device assembly includes a substrate having a patterned metal layer, a first semiconductor die coupled with a first portion of the patterned metal layer, and a plurality of conductive terminals. At least one of the plurality of conductive terminals is coupled with a second portion of the patterned metal layer. The assembly also includes a die attach paddle coupled with a third portion of the patterned metal layer, and a second semiconductor die coupled with the die attach paddle. The assembly further includes a plurality of wire bonds respectively electrically coupling the second semiconductor die with a first conductive terminal of the plurality of conductive terminals, the second semiconductor die with the die attach paddle, the second semiconductor die with the first semiconductor die, and the first semiconductor die with a second conductive terminal of the plurality of conductive terminals.

### SUMMARY

In a general aspect, a semiconductor device assembly includes a substrate having a patterned metal layer, a first semiconductor die coupled with a first portion of the patterned metal layer, and a plurality of conductive terminals. At least one of the plurality of conductive terminals is coupled with a second portion of the patterned metal layer. The assembly further includes a die attach paddle coupled with a third portion of the patterned metal layer, and a second semiconductor die coupled with the die attach paddle. The assembly also includes a first bond wire electrically coupling the second semiconductor die with a first conductive terminal of the plurality of conductive terminals, a second bond wire electrically coupling the second semiconductor die with the die attach paddle, a third bond wire electrically coupling the second semiconductor die with the first semiconductor die, and a fourth bond wire electrically coupling the first semiconductor die with a second conductive terminal of the plurality of conductive terminals.

In another general aspect, a semiconductor device assembly includes a substrate having a first patterned metal layer including a first material, a second patterned metal layer including a second material different than the first material, a first semiconductor die coupled with a first portion of the first patterned metal layer, and a plurality of conductive terminals. At least one of the plurality of conductive terminals is coupled with a second portion of the first patterned metal layer. The assembly further includes a second semiconductor die coupled with the second patterned metal layer. the assembly also includes a first bond wire electrically coupling the second semiconductor die with a first conductive terminal of the plurality of conductive terminals, a second bond wire electrically coupling the second semiconductor die with the second patterned metal layer, a third bond wire electrically coupling the second semiconductor die with the first semiconductor die, and a fourth bond wire electrically coupling the first semiconductor die with a second conductive terminal of the plurality of conductive terminals.

### BRIEF DESCRIPTION OF THE DRAWINGS

FIG. 1A is a diagram schematically illustrating a top plan view of an example semiconductor device assembly.

FIG. 1B is a diagram schematically illustrating a top plan view of another example semiconductor device assembly.

FIG. 2A is a diagram illustrating a perspective view of an example implementation of the semiconductor device assembly of FIG. 1A.

FIG. 2B is a diagram illustrating a top plan view of another example implementation of the semiconductor device assembly of FIG. 1A.

FIG. 3A is a diagram illustrating a perspective view of an example implementation of the semiconductor device assembly of FIG. 1B.

FIG. 3B is a diagram illustrating a perspective view of another example implementation of the semiconductor device assembly of FIG. 1B.

FIG. 3C is diagram illustrating a top plan view of the semiconductor device assembly of FIG. 3B.

FIG. 3D is a diagram illustrating a magnified view of a portion of the semiconductor device assembly of FIG. 3A.

FIG. 4A is a diagram illustrating a top perspective view of an exterior of an example of encapsulated semiconductor device assembly.

FIG. 4B is a diagram illustrating an end view of the semiconductor device assembly shown of FIG. 4A.

FIG. 4C is a diagram illustrating an end view of the power module of FIG. 3B showing internal components of the semiconductor device assembly.

FIG. 5 is a flowchart illustrating another example method for producing a semiconductor device assembly, such as the semiconductor device assemblies of FIG. 1B, and 3A to 3D.

FIG. 6 is a flowchart illustrating an example method for producing a semiconductor device assembly, such as the semiconductor device assemblies of FIGS. 1A, 2A and 2B.

FIGS. 7-11 are diagrams schematically diagrams illustrating a semiconductor device assembly at various stages of manufacturing in accordance with the method of FIG. 6.

FIG. 12 is a diagram illustrating a perspective view of an encapsulated semiconductor device assembly, such as the semiconductor device assemblies of FIGS. 1A to 4C, prior to trim-and-form operations.

FIG. 13 is a diagram illustrating a perspective view perspective view of the semiconductor device assembly of FIG. 12 after performing trim-and-form operations.

Aspects of the present disclosure are best understood from the following detailed description when read with the accompanying figures. The drawings are for purposes of illustrating example implementations and may not necessarily be to scale. For instance, dimensions of the various illustrated features may be arbitrarily increased or reduced for clarity of discussion and/or illustration. In the drawings, like reference symbols may indicate like and/or similar components (elements, structures, etc.) in different views.

The drawings illustrate generally, by way of example, but not by way of limitation, various implementations discussed in the present disclosure. Reference symbols shown in one drawing may not be repeated for the same or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated. Where appropriate, reference axes (x, y, and z axes) are shown for purposes of reference to illustrate respective and relative orientation of the views of different drawings. Reference may be made to these reference axes with respect to dimensions of the illustrated implementations, and/or orientation of elements of those implementations.

### DETAILED DESCRIPTION

Semiconductor device assemblies (e.g., modules, power module, semiconductor device modules, etc.) that include power semiconductor devices can be implemented using multiple semiconductor die, substrates, leadframes, electrical interconnections, a molding compound, etc. Power transistors can be included in one or more of semiconductor die of an assembly. For example, such power transistors can include insulated-gate bipolar transistors (IGBTs), power metal-oxide-semiconductor field effect transistors (MOSFETs), and so forth. Semiconductor die including fast recovery diodes (FRDs) or free-wheeling diodes (FWDs) may be used in conjunction with semiconductor die including power transistors, e.g., for reverse recovery in conjunction with IGBT devices.

Electrical interconnections within such power semiconductor device modules can include, for example, bond wires, conductive spacers, and/or conductive clips. A molding compound, e.g., an epoxy molding compound, can serve as an encapsulant to protect components of the assembly. A plurality of conductive terminal, e.g., included in a leadframe, can be used for supplying power to the semiconductor devices, as well as for transmitting (communicating) input and output signal of the module. High-power semiconductor device assemblies (power modules), encapsulated as semiconductor device modules, can be used in various applications, including electric vehicles (EVs), hybrid electric vehicles (HEVs), home appliances, heating, ventilation, and air conditioning (HVAC) systems, and other industrial applications. For instance, in some implementations, the described approaches can be used to implement a half-bridge power module, a full-bridge power module, a 3-phase half-bridge power module, a multi-phase half-bridge power module, etc., which can be used in automotive applications, industrial applications, and/or consumer electronics applications.

One technical problem with prior power module implementations is an overall size of such modules (e.g., dimensions and/or mass), which can increase their cost due, at least in part, to material costs (e.g., leadframe cost, substrate cost, etc.). Overall size (form factor, footprint, etc.) of current semiconductor device assemblies, e.g., power modules, can also increase the size and cost of associated components, such as cooling components (e.g., heat sinks, fluidic cooling jacket housings, etc.). One technical solution to the foregoing technical problem is to implement such power modules using more space efficient arrangement of components of the module, and/or by integrating multiple components of prior implementations, into a single component.

In some implementations in accordance with this technical solution, semiconductor die included in the module can be implemented using semiconductor materials that allow for higher operating power (e.g., operating current density and/or operating voltage) than prior implementations. For instance, semiconductor devices implemented using silicon carbide (SiC) can be used in place of semiconductor die implemented using silicon (Si). Such implementations, for a given power requirement or power rating of a module, can allow for a reduction in a number of semiconductor die and/or reduced size of semiconductor die included in a semiconductor device assembly, which can facilitate module size reductions as a result of a decrease in a size of an associated substrate to which (on which) the semiconductor die are coupled, such as a direct-bonded metal (DBM) substrate (e.g., a direct-bonded copper (DBC) substrate, an insulated-metal substrate (IMS), a printed circuit board substrate, and so forth.

One technical benefit of the foregoing technical solution is, for a given power module configuration (e.g., a half-bridge circuit) with a given power rating, is a decrease in power module dimensions (e.g., x and y dimensions). For instance, in some implementations, power module dimensions can be decreased so as to achieve a 36% reduction in overall area of a semiconductor device assembly (e.g., power module, package, etc.). Accordingly, size (dimensions, mass) of the power module can be reduced, and reduced size of associated components, such as cooling mechanisms, can also be achieved.

Another benefit of the foregoing of the foregoing technical solution is a reduction in material usage and/or elimination of one or components of a module. For instance usage of copper, substrate material (such as ceramic included in DBM substrate), semiconductor materials, etc., can be reduced as a result of reduced module size. Furthermore, integrating multiple components of prior implementations, such as gate-drive control integrated circuits (ICs) into a single component can also reduce size and cost of the resulting assembly. Such reductions in, or elimination of material usage can reduce cost, size and/or mass of a semiconductor device assembly (module, package, etc.) as compared to prior implementations.

Another technical benefit of the foregoing technical solution is improved reliability. For instance, spacing of components (e.g., semiconductor die, conductive terminals, etc.) that are electrically coupled using bond wires in prior implementations can result in those bond wires being vulnerable to damage or breakage (e.g., due to bond wire length, etc.) and, consequently, can cause reliability failures. In the example implementations described herein, efficient arrangement of components of an assembly can reduce bond wire length, as well as vertical separation of surfaces to which each end of a give bond wire is respectively attached. Accordingly, risk of damage to such bond wires and the associated reliability risk can be reduced.

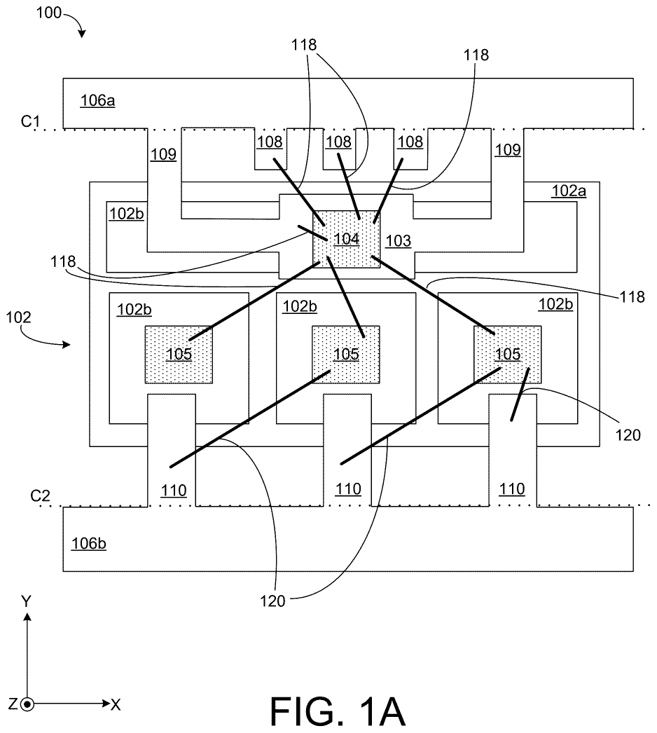

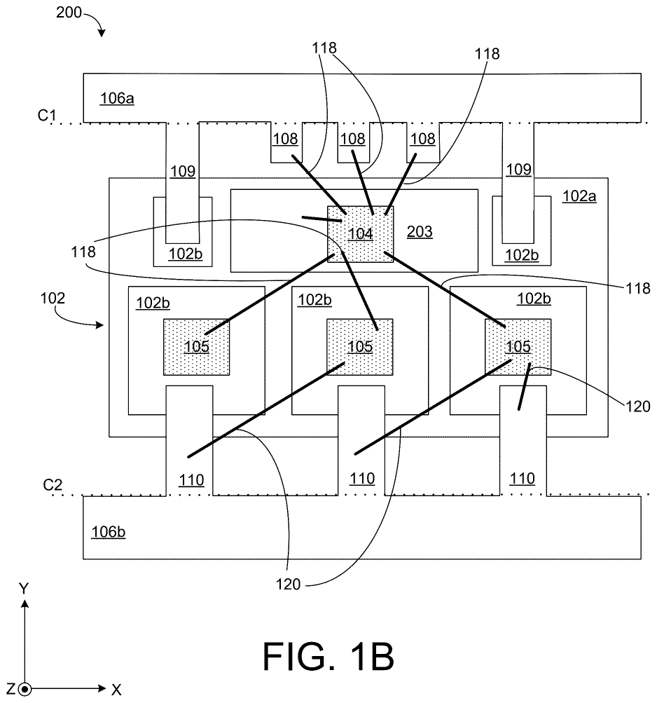

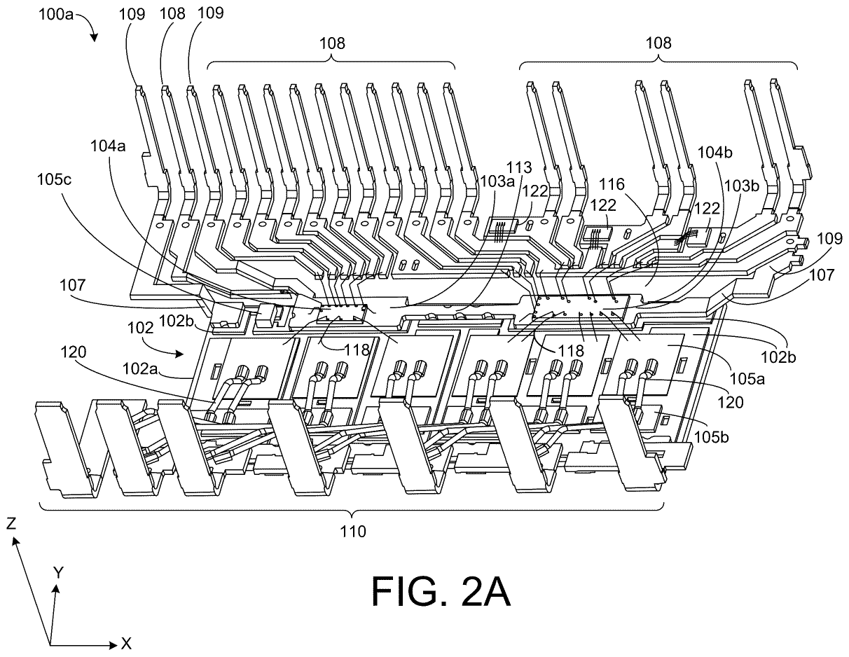

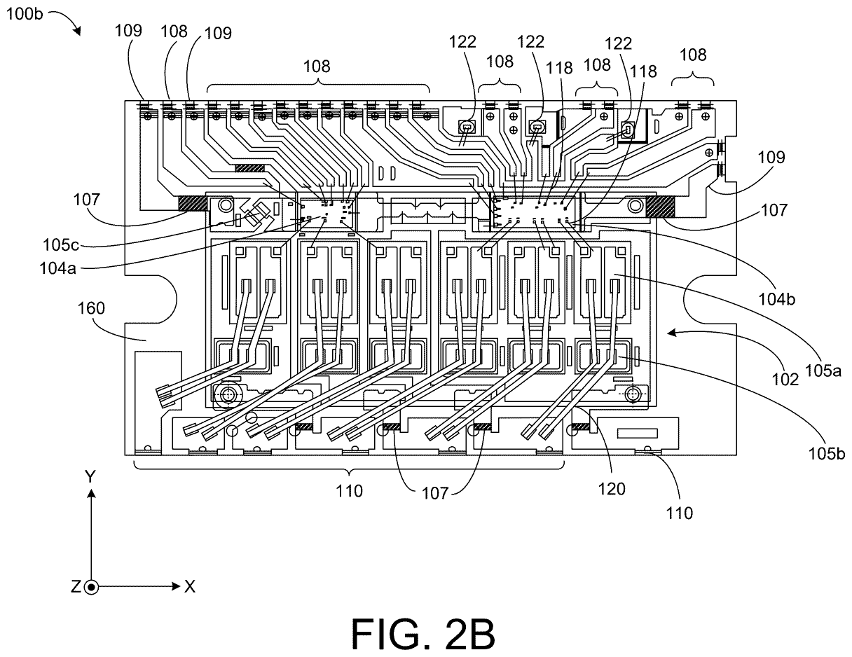

FIG. 1A is a diagram schematically illustrating a top plan view of an example power module or semiconductor device assembly (assembly 100). The arrangement of the assembly 100 is given by way of example and for purposes of illustration. Implementations of the assembly 100, such as those illustrated in FIGS. 2A and 2B can implement various circuits, such as half-bridge circuits, 3-phase half-bridge circuits, and so forth. Of course, the approaches described herein can be used to semiconductor device assemblies that implement other circuits.

In the example of FIG. 1A, the assembly 100 include a substrate 102, which can be a DBM substrate, such as a DBC substrate. In some implementations, as in this example, the substrate 102 (a DBM substrate) includes an insulating layer 102a disposed between a first metal layer (a patterned metal layer 102b) and a second metal layer (not shown in FIG. 1A). The insulating layer 102a can be, for example, a ceramic layer. In some implementations, the insulating layer 102a can be, or can include, for example, a ceramic material such as alumina (Al₂O₃) or aluminum nitride (AlN)).

In some implementations, a DBM substrate can be formed by bonding one or more of the metal layers (e.g., first metal layer (e.g., patterned metal layer 102b), second metal layer) to the insulating layer. In some implementations, one or more of the metal layers can be bonded to the insulating layer using, for example, a high-temperature process and/or a lamination process.

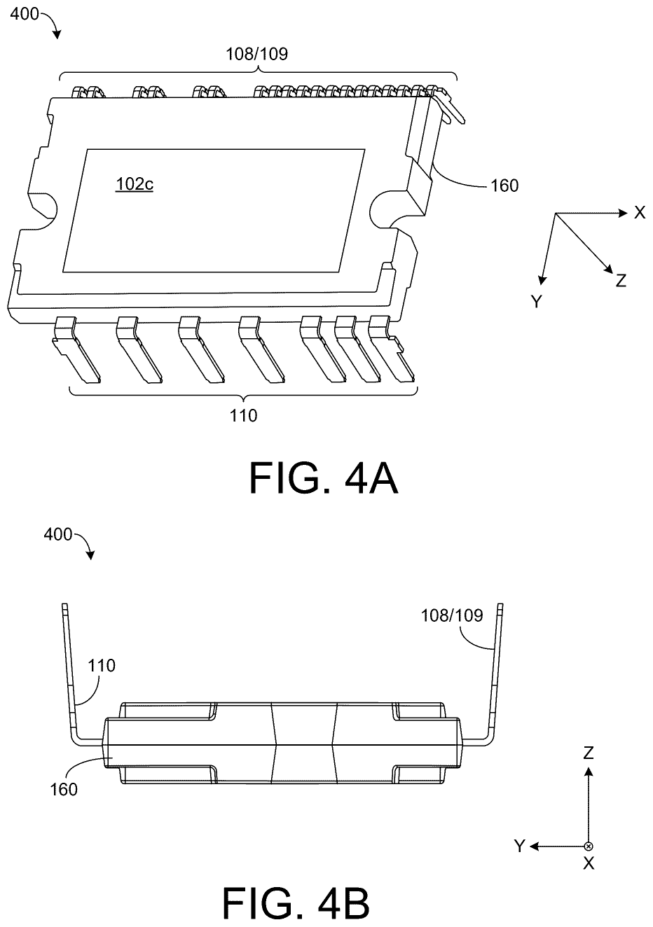

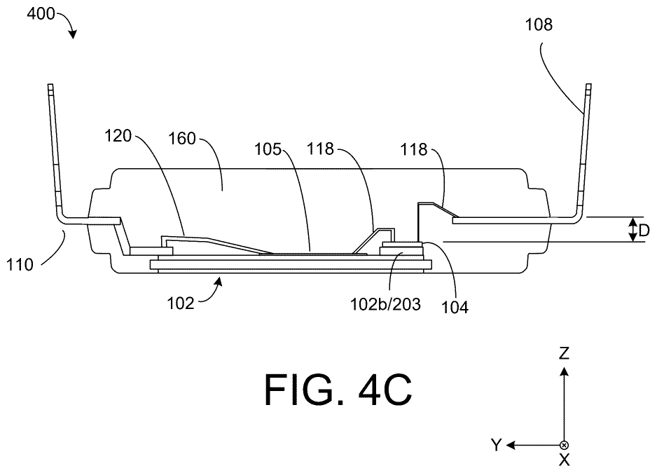

In some implementations, the first metal layer and/or the second metal layer of the DBM substrate can be, or can function as a heat sink. In some implementations, the first metal layer and/or the second metal layer can be coupled to a heat sink or other heat dissipation component. In some implementations, at least a portion of one or more of the first metal layer or the second metal layer can be exposed through a molding material, such as a metal layer 102c as shown in FIG. 4A.

In some implementations, the first metal layer and/or the second metal layer of the DBM substrate can be or can include a patterned metal layer, such as the patterned metal layer 102b, including one or more electrically conductive portions and/or traces, such as shown in FIG. 1A. In some implementations, the first metal layer and/or the second metal layer can be, or can include a patterned layer configured to form one or more electrical circuits, one or more patterned metal layers or metal layer portions, one or more conductive blind and/or through vias, and/or so forth.

In some implementations, a DBM substrate can be, or can include a direct bonded copper (DBC) substrate (e.g., a DBM with copper metal layers). In some implementations, such as in DBC substrate implementations, the first metal layer and/or the second metal layer is a copper layer. In some implementations, the substrate 102 can be an IMS substrate (with an insulating material disposed between the metal layers and the insulating layer 102a, which can be aluminum or other metal. In some implementations, the substrate 102 can be a printed circuit board substrate, or other substrate.

In the example, of FIG. 1A, the assembly 100 includes a leadframe that includes a die attach paddle (DAP) 103 that is coupled with a respective portion of the patterned metal layer 102b. An IC semiconductor die 104 is coupled (soldered, sintered, epoxy attached, etc.) with (to) the DAP 103. In prior semiconductor device assembly implementations, such IC semiconductor die are coupled with portions of the leadframe (DAPs) that are not disposed on (coupled with) an associated substrate, which increases a size of the leadframe and, as a result, a size and cost of the associated package assembly. Accordingly, the configuration of the assembly 100 can provide for reduction in leadframe size, and in turn reduction in size and cost of an associated package assembly including the assembly 100. Furthermore, as compared to prior implementations, the IC semiconductor die 104 can integrate multiple components of prior assemblies. For instance, multiple gate-drive control ICs can be integrated in the IC semiconductor die 104, which can provide for reduced size of the assembly 100 and an associated final package (molded package) by reducing an overall area used to implement the control ICs.

As shown in FIG. 1A, the leadframe also includes a plurality of conductive terminals 108, a plurality of conductive terminals 109, and a plurality of conductive terminals 110. In some implementations, the conductive terminals 108 and 109 can be configured for conducting lower voltages and currents than the conductive terminals 110. Accordingly, the conductive terminals 108 and 109 can be referred to as having a smaller gauge (or size) than the conductive terminals 110. Likewise, the conductive terminals 110 can be configured for conducting higher voltages and currents (e.g., hundreds of volts) and be referred to as having a larger gauge (or size) than the conductive terminal 108 and 109. As shown in FIG. 1A, the conductive terminals 109 can be smaller size terminals that are physically coupled with respective portions of the patterned metal layer 102b and also contiguous with the DAP 103. The conductive terminals 108, in the example of FIG. 1A, are smaller size terminals that are not physically coupled with the substrate 102. In the example of FIG. 1A, each of the conductive terminals 110 is shown as being coupled with respective portions of the patterned metal layer 102b of the substrate 102. In some implementations, such as those described herein, one of more the conductive terminals 110 may not be physically coupled with the substrate 102, similar to the conductive terminals 108.

The leadframe of the assembly 100, in this example, also includes at least one dambar (tie bar, etc.), such as dambar 106a, and dambar 106b, that hold the conductive terminals in their positions relative to one another during an assembly manufacturing process, such those processes described herein. The dambars 106a and 106b can be removed as part of (during) an assembly manufacturing process, e.g., after molding encapsulation, to separate (physically and electrically separate) the conductive terminals 108, 109 and 110 from each other. For instance, the dambar 106a can be removed along cut line C1, while the dambar 106b can be removed along cut line C2.

As shown in FIG. 1A, the assembly 100 also includes a plurality of semiconductor die 105, which can implement discrete power devices, such as IGBT, MOSFETs, diodes, etc. While three semiconductor die 105 are shown in FIG. 1A, in some implementations, additional semiconductor die can be included, e.g., a plurality of IGBT die (e.g., three semiconductor die) along with respective FRD die (e.g., three additional semiconductor die), as an example.

In this example, the assembly 100 further includes small gauge wire bonds 118 and large gauge wire bonds 120. As with the conductive terminals 108 and 109 as compared with the conductive terminals 110, bond wires used to implement the small gauge wire bonds 118 can be configured for conducting lower voltages and currents than the large gauge wire bonds 120. In some implementations, the small gauge wire bonds 118 can be implemented using gold wire, copper wire, a copper alloy wire, etc. Also, as with the conductive terminals 110 as compared to the conductive terminals 108 and 109, the large gauge wire bonds 120 can be configured for conducting higher voltages and currents than the small gauge wire bonds 118. In some implementations, the large gauge wire bonds 120 can be formed using aluminum wire that is of a larger gauge than the wire used to form the small gauge wire bonds 118.

FIG. 1B is a diagram schematically illustrating a top plan view of another example power module or semiconductor device assembly (assembly 200), which, in this example, is a variation of the assembly 100 of FIG. 1A. Accordingly, like or similar elements of the assembly 100 in the assembly 200 are respectively referenced in FIG. 1A with the same reference numbers as those like or similar elements in FIG. 1A. For purposes of brevity, those like or similar elements are not described again in detail with respect to the assembly 200 shown in FIG. 1B. The following discussion of FIG. 1B, instead, describes differences between the assembly 100 and the assembly 200. Accordingly, the assembly 200 is best understood with further reference to, and comparison with FIG. 1B.

As shown in FIG. 1B, the assembly 200 differs from the assembly 100 in that the assembly 200 omits the DAP 103, as well as part of an upper portion of the patterned metal layer 102b of the assembly 100 to which the DAP 103 is coupled. Additionally, the portions of the conductive terminals 109 that laterally connect with the DAP 103 in the assembly 100 are further omitted in the assembly 200. In place of the DAP 103 of the assembly 100 and the underlying portion of the patterned metal layer 102b, the assembly 200 includes a second patterned metal layer (e.g., a plated metal layer 203). In the assembly 200, the IC semiconductor die 104 (e.g., gate-drive control IC) is disposed on (coupled to) the plated metal layer 203. Examples of such plated metal layers are described in further detail hereinbelow. While the assembly 200 in the example of FIG. 1B is similar in configuration to the assembly 100 in FIG. 1A, in some implementations, the configuration of the assembly 200 (arrangement of its components, devices and components included, etc.) can vary from the arrangement shown in FIG. 1B, and differ in more aspects from the arrangement of the assembly 100 shown in FIG. 1A than the assembly 200 as shown.

FIG. 2A is a diagram illustrating a perspective view of a semiconductor device assembly (assembly 100a), which is an implementation of the assembly 100 of FIG. 1A. FIG. 2B is a diagram illustrating a top-down two-dimensional view of another semiconductor device assembly (assembly 100b) that is similar to the assembly 100a. Differences between the assembly 100a and the assembly 100b are described below, following a discussion of the assembly 100a. Also, like 100-series and 200-series references number are used in FIGS. 2A and 2B to refer to like or similar elements of the assembly 100 a and/or the assembly 100b.

As shown in FIG. 2A, the assembly 100a includes a substrate 102. Depending on the particular implementation, the substrate 102 can be a DBM substrate, a DBC substrate, an IMS substrate, a printed circuit board substrate, etc. The assembly 100a further includes a DAP 103a and a DAP 103b that are included in a leadframe of the assembly 100a. The DAP 103a and the DAP 103b are coupled to a portion of a patterned metal layer 102b of the substrate 102. The leadframe of the assembly 100a also includes conductive terminals 108, conductive terminals 109, and conductive terminals 110, such as those described above with respect to, at least, FIG. 1A. For instance, the conductive terminals 109 of the assembly 100a are physically coupled with respective portions of the patterned metal layer 102b of the substrate 102, the conductive terminals 108 are not physically coupled with the substrate 102. Further in the example of FIG. 1A, two of the conductive terminals 110 (the two leftmost conductive terminals 110) are not physically coupled with the substrate 102, while remainder of the conductive terminals 110 are physically (and electrically) coupled with respective portions of the patterned metal layer 102b of the substrate 102.

In this example, the assembly 100a includes an IC semiconductor die 104a and an IC semiconductor die 104b. In this example, the IC semiconductor die 104a can include respective gate-drive control circuits for controlling respective switches, e.g., low-side switches and high-side switches, of a three-phase half-bridge circuit implemented by the assembly 100a. For instance, the IC semiconductor die 104a gate can include a gate-drive control circuit for controlling low-side switches of the circuit, while the IC semiconductor die 104b can include a gate-drive control circuit for controlling low-side switches of the circuit.

In some implementations, such as the assembly 100a of FIG. 2A, IC semiconductor die 104a is coupled (soldered, sintered, epoxy attached, etc.) to the DAP 103a, while the IC semiconductor die 104b is coupled (soldered, sintered, epoxy attached, etc.) to the DAP 103b, where the DAP 103a and the DAP 103b are coupled with a portion of the patterned metal layer 102b of the substrate 102.

In some implementations, the DAPs 103a and 103b can have the form of a substantially rectangular paddle, such as in FIG. 1A, that supports (e.g., provides a mounting surface for) a respective semiconductor die. In some implementations, one or more of the DAPs 103a and/or 103b can have other shapes and/or sizes that may accommodate different form factors (sizes, shapes, etc.) of semiconductor die that are coupled with the DAPs. In some implementations, such as in the example of FIG. 2A, adjacent DAPs (e.g., DAPs 103a and 103b) can be connected by a relatively narrow leadframe portion 113 that has a reduced footprint, e.g., a smaller width, compared with that of the DAPs 103a and 103b. The DAPs 103a and 103b, and the narrow leadframe portions 113, can be arranged in a substantially linear configuration that can also be contiguous with one or more of the conductive terminals 109 (e.g., via lateral portions of the conductive terminals 109, such as in FIG. 1A) that are physically coupled with the substrate 102.

In the example of FIG. 2A, the assembly 100a also includes a plurality of semiconductor die 105a and a plurality of semiconductor die 105b, which can be soldered, sintered, epoxy attached, etc. to respective portions of the 102b. In some implementations, such as the example of FIG. 2A (and FIG. 2B) the semiconductor die 105a can include respective power IGBTs and the semiconductor die105b can include respective FRDs or FWDs, which are coupled with respective portions of the patterned metal layer 102b. In this example, in the view of FIG. 2A, the three left-most semiconductor die 105a, and the three left-most semiconductor die 105b can implement low-side switches and associated FRDs of the three-phase half-bridge circuit. Further in this example,, in the view of FIG. 2A, the three right-most semiconductor die 105a, and the three left-most semiconductor die 105b can implement high-side switches and associated FRDs of the three-phase half-bridge circuit. In some implementations, each pair of semiconductor die 105a and 105b can be replaced by a single, respective semiconductor die that includes a power MOSFET. That is, due to the body-effect of MOSFET devices, the FRDs (semiconductor die 105b) can be omitted in such implementations.

In some implementations, the semiconductor die 105a and 105b can be larger, e.g., thicker, and with larger surface areas than the IC semiconductor die 104a and 104b. In some implementations, the semiconductor die 105a and 105b can operate at, and sustain, higher power levels than the IC semiconductor die 104a and 104b. In some implementations, the semiconductor die 105a and 105b of the assembly 100a can operate in a voltage range of about 600 Volts to about 1700 Volts, and in a current range of about 3 Amps to about 100 Amps.

In some implementations, the semiconductor die 105a and 105b can be formed on a silicon substrate, formed on a silicon carbide (SiC), or can be formed on different substrate types. For instance, in some implementations, different semiconductor die (when more than one semiconductor die is included) can be fabricated using different semiconductor substrates (e.g., a silicon carbide (SiC) substrate, a silicon (Si) substrate, a gallium nitride (GaN) substrate, etc.). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT or MOSFET can be fabricated using a SiC substrate, while a controller (such as the IC semiconductor die 104a and 104b) and/or an FRD (semiconductor die 105b) can be fabricated using a silicon substrate.

In some implementations, the assembly 100a can have x and y dimensions that are at least 30% less than x and y dimensions of previous implementations of three-phase half-bridge power module assemblies, while delivering equivalent thermal performance and electrical performance. Reducing dimensions of an assembly by this amount (e.g., at least 30%) can reduce associated cost of producing an assembly, such as those described herein, by about 20% to about 30%, as compared to prior implementations.

As shown in FIG. 2A, the conductive terminals 109 and at least one of the conductive terminals 108 include a respective sloped portion 107. In some implementations, one or more of the conductive terminals 110 can include such a sloped portion. Such sloped portions 107 can facilitate a multi-level arrangement of the conductive terminals 108 and 109. That is, such a multi-level arrangement allows for a space 116. That is, the space 116 can be a distance between respective surfaces of the conductive terminals 108 to which wire bond attachments are made and a surface of a bond pad of the IC semiconductor die 104a or the IC semiconductor die 104b. In some implementations, the space 116 can be a distance in a range of 0.5 millimeters (mm) to 4 mm that is defined (e.g., along the z-axis). In some implementations, the space 116 can have a y-axis component. Although only one space 116 is shown in FIG. 2A, in some implementations sloped portions 107 can be used to define a similar space 116 between the substrate 102 and portions of the conductive terminals 110.

As shown in FIG. 2A, the conductive terminals 108 and the conductive terminals 109 can be of smaller size (e.g., have a smaller gauge) than a size (gauge) of the conductive terminals 110. That is, in this example, the conductive terminals 108 and the conductive terminals 109 can referred to as smaller-gauge terminals, while the conductive terminals 110 can be referred to as larger-gauge terminals. For instance, the conductive terminals 108 and the conductive terminals 109 can be used for lower voltages and currents than the conductive terminals 110. Accordingly, the conductive terminals 108 and conductive terminals 109 can be referred to as low-power conductive terminals, with the conductive terminals 110 can be referred to as high-power conductive terminals.

In some implementations, a leadframe (e.g., conductive terminals, DAPs, dambars, etc.) of a semiconductor device assembly, such as those described herein. can be cut or stamped from a thin, rolled sheet of metal, e.g., copper, aluminum, etc. In some implementations, different portions of the leadframe can respectively include different conductive materials. For instance, some portion of a leadframe can include copper and other portions of the leadframe can include aluminum. In some implementations, nickel or silver can be plated, e.g., strip plated, on surfaces of the leadframe to increase wire bond strength. In some implementations, the DAPs 103a and 103b may facilitate dissipation of heat from the IC semiconductor die 104a and 104b.

The assembly 100a also includes a plurality of boot-strap devices 122, which can facilitate power supply charging for the IC semiconductor die 104b (e.g., gate-drive control IC for the low-side switches). In some implementations. each of the boot-strap devices 122 can include a boot-strap diode (BSD) and a boot-strap resistor (BSR). Accordingly, the boot-strap devices 122 can be referred to as boot-strap diode and resistor (BSDR) devices.

As shown in FIG. 2A, as with the assembly 100 of FIG. 1A, the assembly 100a includes small gauge wire bonds 118 for carrying small voltages and/or currents, and large gauge wire bonds 120 for carrying large currents. For instance, the small gauge wire bonds 118 are used to electrically couple the conductive terminals 108 and/or 109 respectively with the IC semiconductor die 104a and 104b, electrically couple the boot-strap devices 122 respective conductive terminals of the conductive terminals 108, and to electrically couple the IC semiconductor die 104a and 104b with the semiconductor die 105a.

As with the assembly 100 of the FIG. 1A, in FIG. 2A, the large gauge wire bonds 120 electrically couple the 110 with the semiconductor die 105a and 105b. As described herein, the small gauge wire bonds 118 can be made of gold, copper, an alloy of copper, etc., while the large gauge wire bonds 120 can be made of aluminum. In some implementations, the small gauge wire bonds 118 can have diameters in a range of about 1 mil to about 2 mils, or about 25 μm. In some implementations, the large gauge wire bonds 120 can have diameters in a range of about 5 mils to about 20 mils.

In the example of FIG. 2A, the assembly 100a further includes a temperature-sensing device 105c, which can have a first terminal coupled with a first portion of the patterned metal layer 102b and a second terminal coupled with a second portion of the patterned metal layer 102b. That is, the 105c can be bridged between two separate portions of the patterned metal layer 102b. In some implementations, the temperature-sensing device 105c can be a negative temperature coefficient (NTC) device, a positive temperature coefficient (PTC), or other temperature-sensing device 105c. In this example, electrical signals received from, or provided to the temperature-sensing device 105c can be communicated on one or more conductive terminal of the conductive terminals 109.

As noted above, FIG. 2B is a diagram illustrating a top plan view of the assembly 100b, which is another implementation of the assembly 100 of FIG. 1A and a variation of the assembly 100a of FIG. 2A. The view of FIG. 2B illustrates an interior view of components of the assembly 100b. For reference purposes, an outline of a molding compound 160 is shown in FIG. 2B. In some implementations, the molding compound 160 can be used to encapsulate portions of the assembly 100b (or other assemblies described herein) to protect those components contained with the molding compound 160 from environmental factors, such as moisture, dust, vibration, etc.

As noted above, the assembly 100b of FIG. 2B is a variation of the assembly 100a of FIG. 2A. Accordingly, like or similar elements of the assembly 100a in the assembly 100b are respectively referenced in FIG. 2B with the same reference numbers as those like or similar elements in FIG. 2A. For purposes of brevity, those like or similar elements are not described again in detail with respect to the assembly 100b shown in FIG. 2B. The following discussion of FIG. 2B, instead, describes differences between the assembly 100b and the assembly 100a. Accordingly, the assembly 100b is best understood with further reference to, and comparison with FIG. 2A, as well as FIG. 1A.

As compared with the assembly 100a, the assembly 100b differs in configuration of the conductive terminals 108, the conductive terminals 109 and the conductive terminals 110. For instance, at least some of the conductive terminals are differently shaped than those of assembly 100a, sloped portions 107 are differently sized and/or located, and sloped portions 107 are included in at least some of the conductive terminals 110. Also, the arrangement of at least some of the small gauge wire bonds 118 in the assembly 100b differs from that illustrated for the assembly 100a. The particular arrangement of such elements of a semiconductor device assembly will depend on the particular implementation.

The assembly 100b also differs from the assembly 100a in the orientation of the temperature-sensing device 105c and the corresponding layout of associated portions of the patterned metal layer 102b that the temperature-sensing device 105c bridges. For instance, the temperature-sensing device 105c of the assembly 100b is angled with respect to the y-axis, with the associated portions of the patterned metal layer 102b also including angled edges. Such an arrangement can, in some implementations, provide for more efficient use of space (surface area) of the substrate 102 than other possible arrangements, such as where associated portions of the patterned metal layer 102b that the temperature-sensing device 105c bridges are arranged side-by-side along the x-axis.

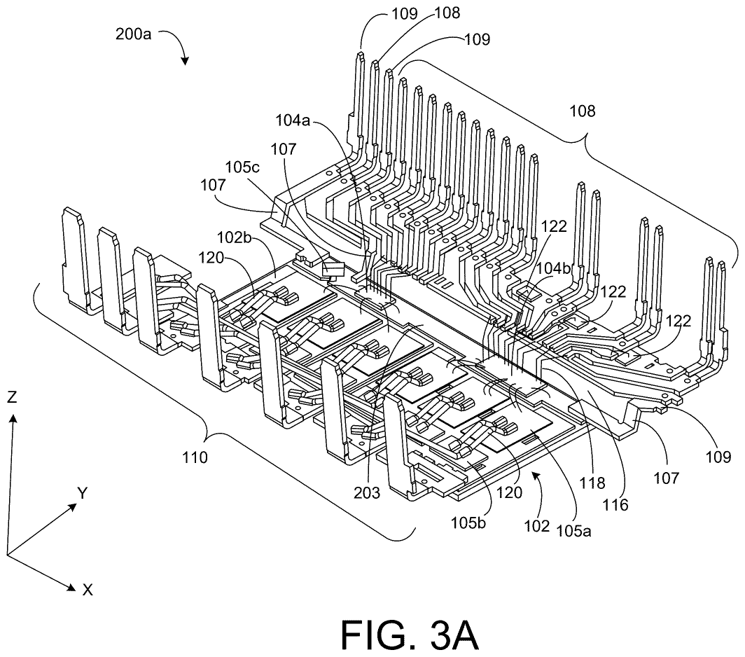

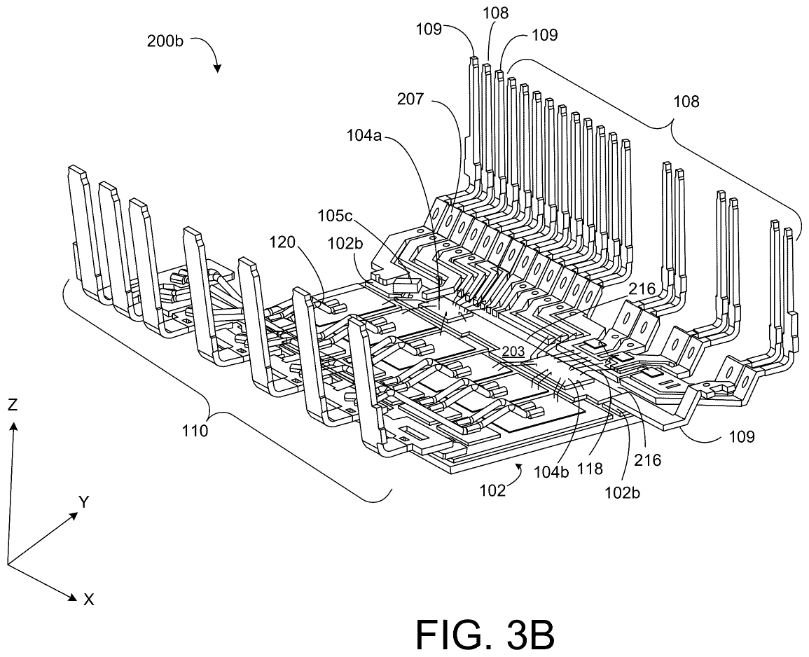

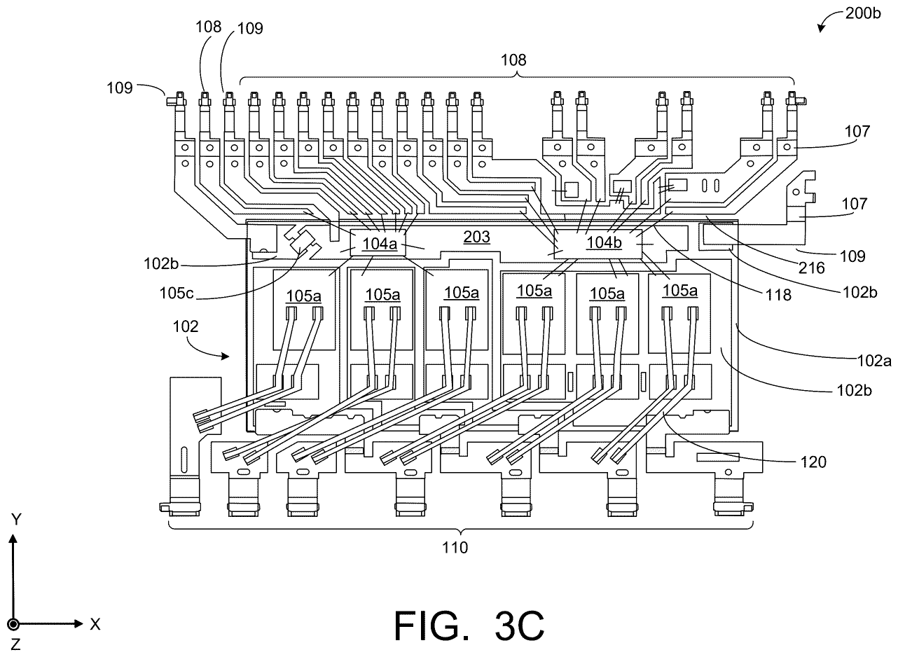

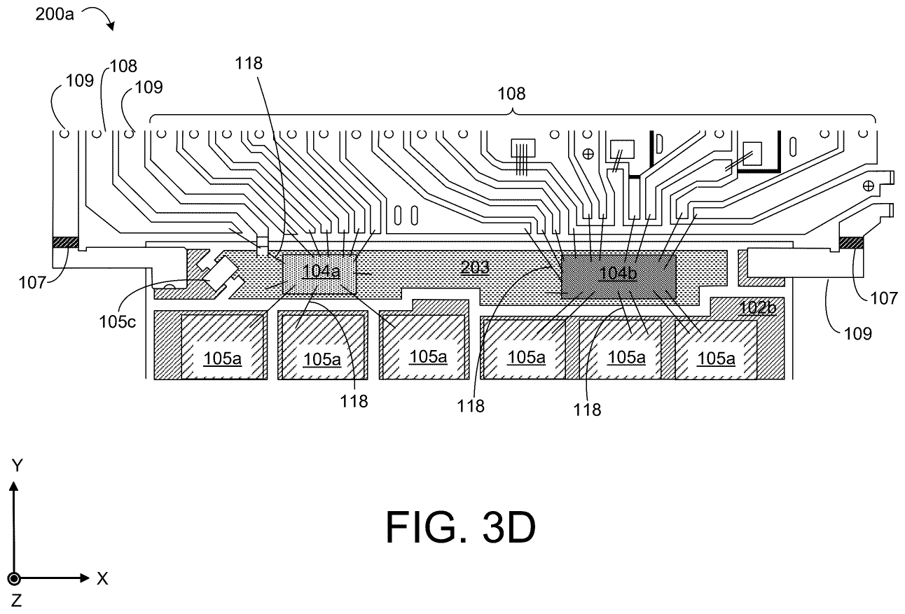

FIG. 3A is a diagram illustrating a perspective view of a semiconductor device assembly 200a, which is an implementation of the semiconductor device assembly 200 of FIG. 1B. FIG. 3B is a diagram illustrating a perspective view of a semiconductor device assembly 200b, which is an implementation of the semiconductor device assembly 200 of FIG. 1B and a variation of the semiconductor device assembly 200a of FIG. 3A. FIG. 3C is a top plan view illustrating a perspective view of the semiconductor device assembly 200b of FIG. 3B. FIG. 3D is a diagram illustrating a magnified, top plan view of a portion of the semiconductor device assembly 200a of FIG. 3A.

As with the assembly 100 of FIG. 1A and the assembly 200 of FIG. 1B, the semiconductor device assembly 200a of FIG. 2A is a variation of the assembly 100a of FIG. 1A (and similarly varies from the assembly 100b of FIG. 2B). Accordingly, like or similar elements of the assembly 100a (or the assembly 100b) in the assembly 200a are respectively referenced in FIG. 3A with the same reference numbers as those like or similar elements in FIGS. 2A and/or 2B. For purposes of brevity, those like or similar elements are not described again in detail with respect to the assembly 200a shown in FIG. 3A. The following discussion of FIG. 3A, instead, describes differences between the assembly 100a (or the assembly 100b) and the assembly 200a Accordingly, the assembly 200a, in the following discussion, is best understood with further reference to, and comparison with FIG. 2A or FIG. 2B.

As with the assembly 100 and the assembly 200, the assembly 200a similarly differs from the assembly 100a or the assembly 100b in that the assembly 200 omits the DAPs 103a and 103, the relatively narrow leadframe portion 113, as well as part of an upper portion of the patterned metal layer 102b of the assembly 100 to which the DAP 103 is coupled. Additionally, the portions of the conductive terminals 109 of the 100a and the 100b that laterally connect with the DAPs 103a and 103b are further omitted in the assembly 200a. In place of the DAPs 103a and 103b, the relatively narrow leadframe portion 113 and the underlying portion of the patterned metal layer 102b, the assembly 200a includes a second patterned metal layer (e.g., a plated metal layer 203). In the assembly 200a, the IC semiconductor die 104a and 104b (e.g., gate-drive control ICs) are disposed on (coupled to) the plated metal layer 203. Examples of such plated metal layers are described in further detail hereinbelow. Briefly, however, the plated metal layer 203 can include can include silver and/or gold, which can facilitate formation of high-quality and reliable wire bonds with the plated metal layer 203. In some implementations, the plated metal layer 203 can be ground or polished to provide an appropriate surface for forming high-quality and reliable wire bonds to a surface of the plated metal layer 203.

As compared with the assembly 100a, the assembly 200b also differs in configuration of the conductive terminals 108, the conductive terminals 109, and the conductive terminals 110. For instance, at least some of the conductive terminals are differently shaped than those of assembly 100a, and sloped portions 107 are differently sized and/or located. The particular arrangement of such elements (as well as other elements) of a semiconductor device assembly will depend on the particular implementation.

The assembly 200a, as with the assembly 100b, also differs from the assembly 100a in the orientation of the temperature-sensing device 105c and the corresponding layout of associated portions of the patterned metal layer 102b that the temperature-sensing device 105c bridges. For instance, the temperature-sensing device 105c of the assembly 100b is angled with respect to the y-axis, with the associated portions of the patterned metal layer 102b also including angled edges. Such an arrangement can, in some implementations, provide for more efficient use of space (surface area) of the substrate 102 than other possible arrangements, such as where associated portions of the patterned metal layer 102b that the temperature-sensing device 105c bridges are arranged side-by-side along the x-axis.

While the assembly 200a in the example of FIG. 3A is similar in configuration to the assembly 100 in FIG. 1A in a number of aspects, in some implementations, the configuration of the assembly 200a (arrangement of its components, devices and components included, etc.) can vary from the arrangement shown in FIG. 3A, and differ in more aspects from the arrangement of the assembly 100a shown in FIG. 2A than the assembly 200a as shown.

FIG. 3B illustrates a perspective view of the assembly 200b, which, as noted above, is a variation of the assembly 200a of FIG. 3A. Accordingly, like or similar elements of the assembly 200a in the assembly 200b are respectively referenced in FIG. 3B with the same reference numbers as those like or similar elements in FIG. 3A. For purposes of brevity, those like or similar elements are not described again in detail with respect to the assembly 200b shown in FIG. 3B. The following discussion of FIG. 3B, instead, describes differences between the assembly 200b and the assembly 200a. Accordingly, the assembly 200b is best understood with further reference to, and comparison with FIG. 3A.

As compared with the assembly 200a, the assembly 200b differs in configuration of the conductive terminals 108, the conductive terminals 109 and the conductive terminals 110. For instance, at least some of the conductive terminals are differently shaped than those of assembly 100a, and sloped portions 207 are differently sized and/or located. Also, the arrangement of at least some of the small gauge wire bonds 118 in the assembly 100b differs from that illustrated for the assembly 100a. The particular arrangement of such elements of a semiconductor device assembly will depend on the particular implementation.

The 200b also differs in that a gap 216 between the conductive terminals 108 and 109 and the substrate is primarily (substantially, nearly all, etc.) in the y-axis, as compared to the space 116 of the assembly 200a and the assembly 100b, which include components in both the y-axis and the z-axis). That is, the gap 216, which is a gap between the substrate 102 and surfaces of the conductive terminals 108 and 109 to which wire bond connections are made, is substantially horizontal, e.g., along the y-axis, without any significant vertical component, e.g., along the z-axis. In other words, in some implementations, the gap 216 of the assembly 200b can be smaller than the space 116 of the assembly 200a, which can allow for further reducing an overall size of the assembly 200b as compared to the assembly 200a (as well as the assemblies 100a and 100b).

In the assembly 200b, surfaces of the IC semiconductor die 104a and the 104b on which small gauge wire bonds 118 are connected can be coplanar with surfaces of the conductive terminals 108 and 109 with which those small gauge wire bonds 118 (e.g., opposite ends of the small gauge wire bonds 118) are connected. As used herein, coplanar can be defined as being coplanar within material dimension tolerances and/or manufacturing variation tolerances. Accordingly, as used herein, the term coplanar may not indicate ideally (or geometrically) coplanar, but that geometric coplanarity is an ideal result.

In the example of FIG. 2B, the gap 216 (smaller compared with a size and vertical component of the space 116 of the assemblies 100a, 100b and 200a) can allow for further reduction in an overall size of the assembly 200b as compared with the assemblies 100a, 100b and 200. Additionally, the gap 216 comparatively allows for shorter wire bonds (small gauge wire bonds 118) in place of longer wire bonds (small gauge wire bonds 118) of the assemblies 100a, 100b and 200a. Furthermore, because the small gauge wire bonds 118 of the assembly 200b do not include a significant vertical portion (because they extend between co-planar elements) and are shorter in length, those small gauge wire bonds 118 can be less prone to damage, such as wire sweep during molding encapsulation, therefore, can be more reliable.

As was indicated above, FIG. 3C is a diagram illustrating a top plan view of the assembly 200b of FIG. 3B. That is, FIG. 3C illustrates a two-dimensional representation of the structure of the assembly 200b, where surfaces of the conductive terminals 108 and 109 with which wire bond connections are made are co-planar with corresponding surfaces of the IC semiconductor die 104a and 104b (e.g., surfaces to which wire bond connections are made with bond pads). In the example implementation shown in FIG. 3C, the IC semiconductor die 104a and 104b are mounted on (coupled with, directly coupled with) the plated metal layer 203. In some implementations of the assembly 200b, the IC semiconductor die 104a and 104 can be mounted on (coupled with, etc.) DAPs disposed on a portion of the patterned metal layer 102b of the substrate 102, such as in the arrangement shown in FIGS. 2A and 2B.

FIG. 3D, as noted above, is a magnified view of a portion of the assembly 200a of FIG. 3A including the IC semiconductor die 104a and 104b. As shown in FIG. 3D, the IC semiconductor die 104a and 104a are coupled with the plated metal layer 203, which can be a silver-based, patterned, plated metal layer, or a gold-based, patterned, plated metal layer. In some implementations, the plated metal layer 203 can be patterned, e.g., by selective plating. Selective plating can be achieved using chemical plating or electric plating, e.g., electroplating or electro-less plating. In some implementations, a gold-based plated layer (e.g., plated metal layer 203) can include gold that is alloyed with other metals, e.g., nickel to form NiAu (nickel gold), or nickel and palladium to form NiPdAu (nickel palladium gold). In some implementations, an exposed surface of the insulating layer 102a can be prepared for plating by performing grinding and/or polishing operations to decrease surface roughness of the ceramic material. Such grinding and/or polishing can facilitate formation of the plated metal layer 203 with a smooth upper surface, which can help to achieve high-quality and reliable wire bonds (small gauge wire bonds 118), e.g., with the plated metal layer 203.

FIGS. 4A and 4B are diagrams illustrating an encapsulated semiconductor device assembly (device package 400). FIG. 4A illustrates a perspective view of the device package 400, while FIG. 4B illustrates an end view of the device package 400. In this example, the device package 400 can include a semiconductor device assembly, such as those described herein. As shown in FIGS. 4A and 4B portions of an included semiconductor device assembly can be encapsulated in a molding compound 160 such that they are not externally visible. As shown in FIGS. 4A and 4B, portions of the conductive terminals 108, 109 and/or 110 can extend outside of the molding compound 160, e.g., for facilitating connection to external elements, such as power supplies, and/or other electronic devices (e.g., semiconductor devices, passive devices, etc.).

As shown in FIG. 4A, a metal layer 102c of a substrate, e.g., the substrate 102, can be exposed through the molding compound 160. The substrate of the device package 400 can take various forms, such as those described herein. In some implementations, the metal layer 102c can act as a thermal dissipation device, e.g., a heat sink, to dissipate thermal energy produced during electrical operation of the device package 400. In some implementations, the metal layer 102c can be coupled with an external thermal dissipation device, such as a passive heat sink, or an actively cooled fluidic heat pipe, as some examples.

In some implementations, the molding compound 160 can be a polymer material, such as an epoxy molding compound (EMC). The molding compound 160 can seal and protect various components of the device package 400, such as semiconductor die, a substrate, wire bonds, conductive clips, etc. In some implementations, the molding compound 160 can be in the form of a gel, e.g., a silicone gel, contained within a polymer (plastic) case instead of an EMC. Implementations including such a silicone gel and plastic case can be used to accommodate more complex circuit assemblies and/or assemblies with larger footprints., e.g., to reduce or prevent a risk of warpage. In some implementations, a plastic case can be used with a busbar electrical connection instead of using a leadframe.

As shown in FIG. 4B, the conductive terminals 108 and 109 can extend out of one sidewall of the molding compound 160, while the conductive terminals 110 can extend out of an opposite sidewall of the molding compound 160, thus facilitating electrical connections with external elements.

FIG. 4C schematically illustrates an end view of the device package 400 (e.g., corresponding with the end view show components of the device package 400 within the molding compound 160 (e.g., an interior view). For instance, FIG. 4C, illustrates a IC semiconductor die 104 that is coupled with a mounting surface, which can be a DAP 103 (disposed on a portion of a patterned metal layer, which is not shown) or a plated metal layer 203. FIG. 4C further illustrates a semiconductor die 105 (e.g., a power MOSFET) that is disposed on (coupled with) the substrate 102, such as on a portion of a patterned metal layer 102b (not shown) of the substrate 102. The device package 400, as shown in FIG. 4C, includes small gauge wire bonds 118 and large gauge wire bonds 120, such those described herein.

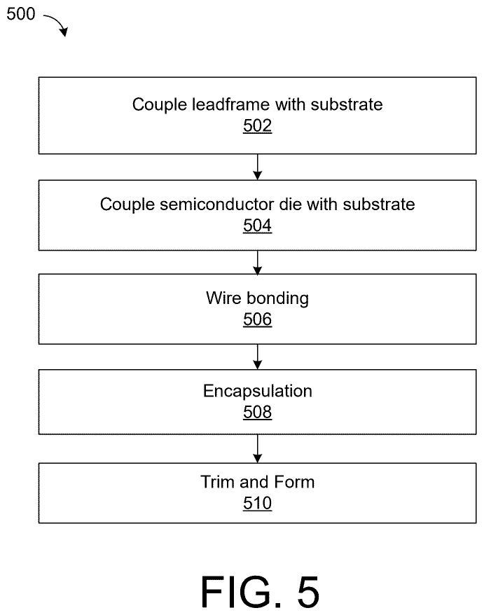

FIG. 5 is a flowchart that illustrates a method 500 for producing a semiconductor device assembly, such as the assemblies of FIGS. 1B, 3A-3D and 4A-4C. Of course, the method 500 can be used to produce other assemblies, such as those descried herein. In some implementations, operations of the method 500 can be performed in conjunction with, in addition to, and/or in place of operations of the method 600 discussed below. Likewise, in some implementations. operations of the method 600 can be performed in conjunction with, in addition to, and/or in place of operations of the method 500. For purposes of illustration, the method 500 will be described with respect to, at least, the assembly 200 of FIG. 1B.

At operation 502, the method 500 includes coupling (soldering, sintering, etc.) a leadframe (e.g., the conductive terminals 109 and the conductive terminals 110) to a substrate, such as respective portions of the patterned metal layer 102b of the substrate 102. At operation 504, the method 500 includes coupling (soldering, sintering, etc.) semiconductor die with the substrate. For instance, the operation 504 can include coupling the semiconductor die 105 with respective portions of the patterned metal layer 102b and coupling the IC semiconductor die 104 with the plated metal layer 203. At operation 506, the method includes wire bonding, e.g., to form the small gauge wire bonds 118 and the large gauge wire bonds 120. At operation 508, the method 500 include performing an encapsulation operation, such as those described herein. At operation 510, the method 500 includes performing trim and form operations to bend the conductive terminals 108, 109 and 110 into their final configurations, e.g., in the configurations of the device package 400. In some implementations, operation 510 can be performed as described below with respect to the method 600 (e.g., operation 616).

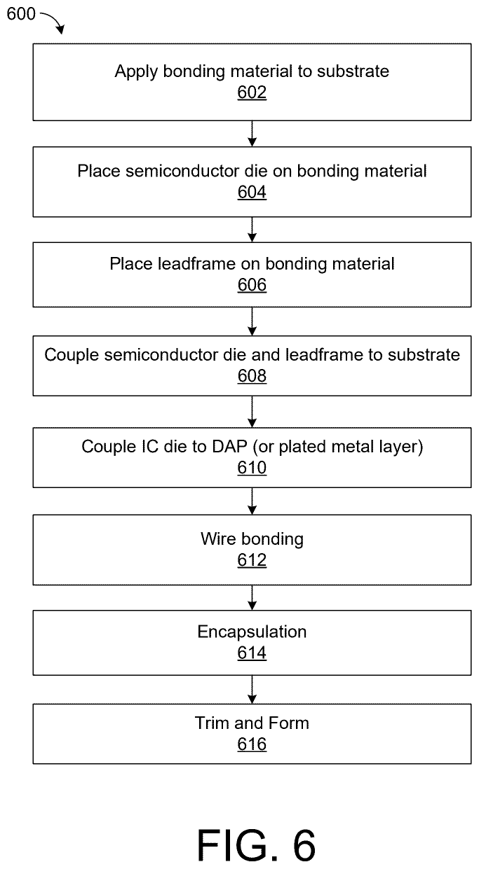

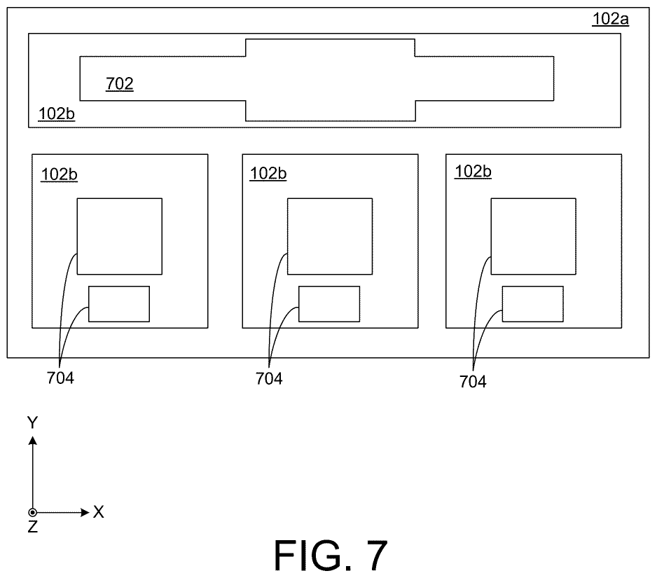

FIG. 6 is a flowchart illustrating a method 600 for fabricating a semiconductor device assembly, e.g., an implementation of the assembly 100 of FIG. 1A, the assembly 100a of FIG. 2A, and/or the assembly 200b of FIG. 2B. As noted above, one or more of the operations of the method 600, or similar operations can be used to implement the method 500 of FIG. 5 to produce a semiconductor device assembly (power module), e.g., implementations of the assembly 200 of FIG. 1B, the assembly 200a of FIG. 3A, the assembly 200b of FIGS. 3B and 3D, and/or the assembly 200b of FIG. 3C.

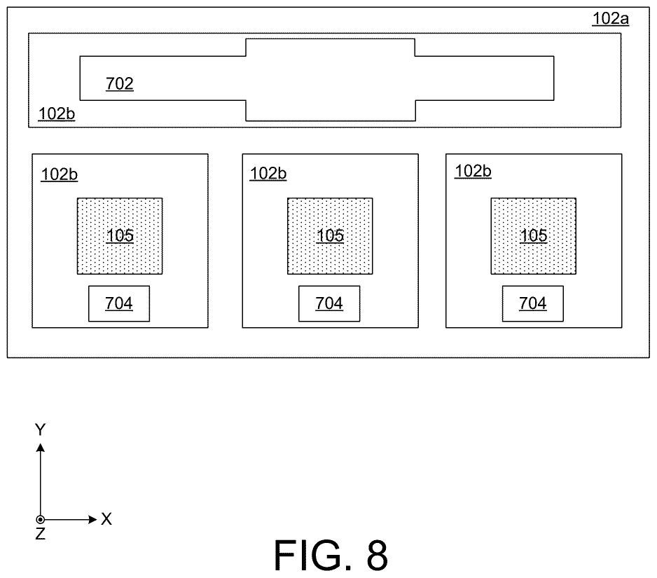

By way of example, and for purposes of illustration, operations 602-610 of the method 600 are described in the context of producing an implementation of the assembly 100 (power module) of FIG. 1A. Also by way of example, and for purposes of illustration, operations 612-616 are described in the context of producing the device package 400 of FIGS. 4A to 4C, e.g., where the device package 400 can include the assembly 100 produced by operations 602—610 of the method 600, or other assemblies described herein. The method 600 is also described with further reference to FIGS. 7-13.

In some implementations, the method 600 can include additional operations, and/or one or more of operations 602-616 can be omitted. For instance, an IC die (e.g., a gate-drive control IC) can be coupled with a DAP of a leadframe prior to attachment to a placement on a substrate at operation 606, and operation 610 can be omitted. In some implementations, the operations 602-616 of the method 600 can be performed in a different order than shown in FIG. 6, and/or one or more operations of the method 600 can be combined. For instance, in some implementations, operation 608 and 610 of the method 600 can be combined, e.g., performed in a single operation.

At operation 602, the method 600 includes applying bonding material on a substrate, such as shown in FIG. 7. For instance, operation 602 can include applying bonding material 702 and bonding material 704 on respective portions of the patterned metal layer 102b. In some implementations, operation 602 can include printing a bonding material, such as a solder paste, a sinter paste, and/or a conductive epoxy paste. In some implementations, operation 602 can include applying one more solder preform films or one or more sintering preform films. That is, the bonding material of operation 602 (e.g., bonding material 702 and bonding material 704) can be applied to portions of a patterned metal layer of a substrate, such as a patterned metal layer of a DBM substrate, e.g., a DBC substrate.

At operation 604, the method 600 includes placing semiconductor die on bonding material of operation 602. For instance, as shown in the FIG. 8, semiconductor die 105 (e.g., power semiconductor die) can be placed on respective portions of the bonding material 704. In some implementations, the semiconductor die can be power transistors of a semiconductor device power module, such as FET devices or IGBT devices. In some implementations, while not specifically shown in FIG. 8, additional semiconductor die (e.g., fast-recovery diodes corresponding with the power transistors) can be placed on respective portions of the bonding material at operation 604.

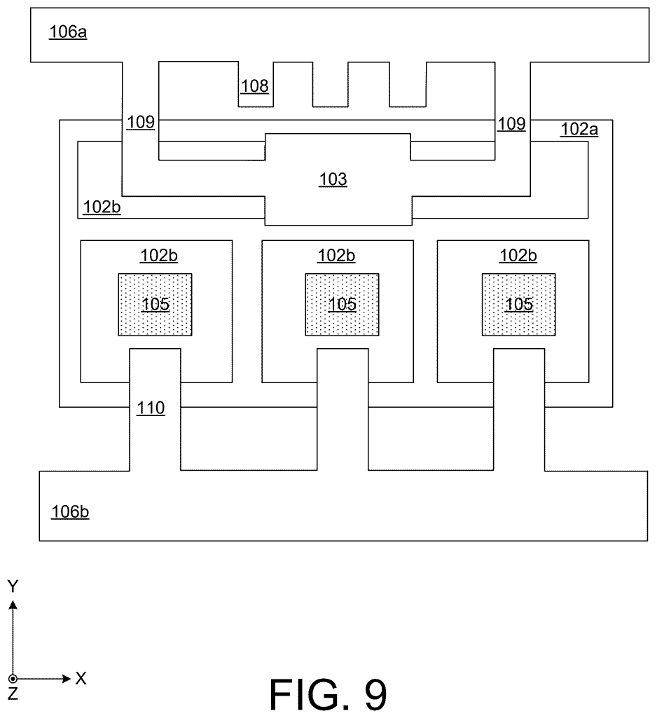

At operation 606, the method 600 includes placing (positioning) a leadframe on the bonding material 702 and respective portions of the bonding material 704, such as shown in the arrangement shown in FIG. 9. For instance, as shown in FIG. 9, the DAP 103 and respective portions of the conductive terminals 109 can be placed (positioned) on the bonding material 702, while respective portions of the conductive terminals 110 can be placed (positioned) on respective portions of the bonding material 704.

In some implementations, e.g., implementations of the assembly 200 of FIG. 1B, the DAP 103 along with a corresponding portion of the patterned metal layer 102b can be omitted, and a plated metal layer, e.g., plated metal layer 203, including gold or silver can be formed in place of the DAP 103. For instance, the plated metal layer 203 can facilitate attachment of one of more control IC, such as gate-drive control ICs, as well as respective bond wire connections to the control IC. In some implementations, semiconductor die disposed on the plated metal layer 203 can be coupled with a surface of the plated metal layer using a soft solder process. In some implementations, use of such a soft solder process can provide efficiency advantages, such as improved thermal conductivity and/or reduced electrical resistance, compared with, at least, epoxy die attach processes.

At operation 608, the method 600 includes coupling the semiconductor die of operation 604 and the leadframe of operation 606 with the corresponding substrate (e.g., with the patterned metal layer 102b) using the bonding material 702 and the bonding material 704. In some implementations, operation 608 can include a solder reflow process, a sintering process or an epoxy cure process, depending on the type of bonding material applied at operation 602.

In a solder reflow process, the bonding material 702 and the bonding material 704 can include a solder paste or solder preform film. The solder reflow process includes melting the solder material to attach couple (physically and electrically couple) semiconductor die 105, the DAP 103, the conductive terminals 109, and the conductive terminals 110 to the patterned metal layer 102b of the substrate. For instance, solder material can be melted in a reflow process by exposing the solder to hot gases, e.g., nitrogen and/or air. In some implementations, a reflow process can heat the solder material to approximately 400 degrees C. Upon cooling, the solder material solidifies to physically and electrically couple the DAP 103,the semiconductor die 105, the conductive terminals 108, the conductive terminals 109 and the conductive terminals 110 with the patterned metal layer 102b. That is, in some implementations, soldering can be, or can include a process of joining two surfaces (e.g., metal surfaces and semiconductor surfaces) together using a molten filler metal (e.g., metal alloy, Tin (Sn), Lead (Pb), Silver (Ag), Copper (Cu)) that can be referred to as a solder.

In a sintering process, the bonding material 702 and the bonding material 704 can include a sintering paste, such as a silver sintering paste, or sintering preform films, such silver sintering preform films. The sintering process can include applying high temperatures while applying pressure to elements being that are being attached using a sintering material (e.g., applying pressure to the DAP 103, the semiconductor die 105, the conductive terminals 108, the conductive terminals 109, and the conductive terminal 110). This process removes gaps between particles of the sintering material and, as a result, densifies the sintering material. In some embodiments, sintered silver has superior material properties when compared to solder, including higher thermal conductivity, higher electrical conductivity, and better reliability. In some implementations, a copper or silver paste can be mixed with a sintering powder that is printed at operation 602.

That is, in some implementations, sintering can be or can include a process of fusing particles together into one solid mass by using, for example, a combination of pressure and/or heat without melting the materials. In some implementations, sintering can include making a sintering material (e.g., a powdered material, a paste material, a film material, etc.) coalesce into a solid or porous mass by heating it, and usually also compressing the material, without liquefaction. In some implementations, materials that can be used for sintering can include metals such as silver (Ag), copper (Cu), and/or metal alloys. In some implementations, sintered connections can have desirable electrical and/or thermal conductivity, durability, and a relatively high melting temperature.

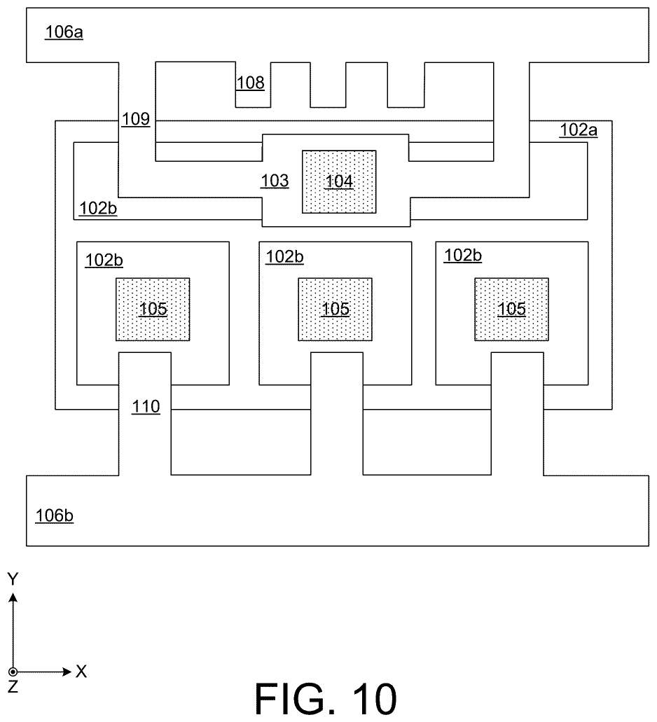

At operation 610, the method 600 may include coupling one or more of the IC semiconductor die 104, e.g., gate-drive control ICs, to the DAP 103 (or to a plated metal layer, such as in implementations of the assembly 200 of FIG. 1B). An arrangement of an example result of operation 610 is shown in FIG. 10, where the IC semiconductor die 104 is coupled with the DAP 103. In some implementations, the IC semiconductor die 104 can be coupled to the DAP 103 using an epoxy and an epoxy bonder machine. In such approaches, an epoxy resin can be applied to the DAP 103. After applying the epoxy resin, the IC semiconductor die 104 can be placed on the epoxy by the epoxy bonder machine, which is followed by a baking cure operation (e.g., in an oven at 200 degree Celsius) to harden (cure) the epoxy resin. In some implementations, such as was noted above, the operation 610 can be carried out prior to operation 606, where the leadframe (conductive terminals and/or an associated DAP of the leadframe) are placed on the bonding material (bonding material 702 and bonding material 704) of operation 602. In some implementations, the IC semiconductor die 104 can be coupled to the DAP 103 using a soldering or sintering process.

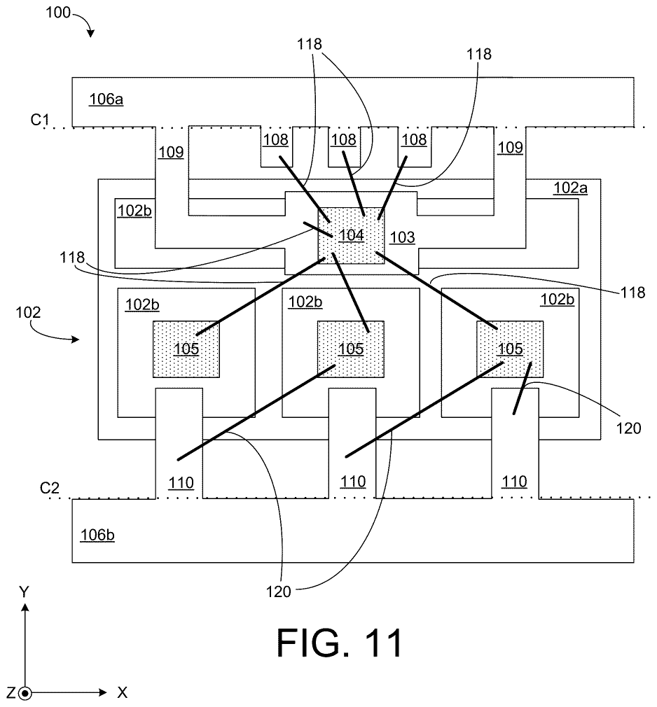

At operation 612, the method 600 includes electrically coupling elements of a semiconductor device assembly being produced using wire bonds, such as shown in FIG. 11, where FIG. 11 is a replication of the schematic illustration of the assembly 100 of FIG. 1A. In some implementations, such as implementations in which respective power transistors are included in the semiconductor die 105, gate terminals and sense terminals (e.g., source sense terminals) of the power transistors can be coupled with terminals (e.g., bond pads) of the IC semiconductor die 104 with respective small gauge wire bonds 118. Additionally, other terminals of the IC semiconductor die 104 can be coupled to the conductive the conductive terminals 108 (smaller gauge terminals) by respective small gauge wire bonds 118.

In some implementations, terminals of the semiconductor die 105 (e.g., source or emitter terminals) can be coupled to the conductive terminals 110 (larger gauge terminals) by respective large gauge wire bonds 120. In implementations including one more diodes (e.g., fast-recovery diodes of free-wheeling diodes), such as the examples of FIGS. 2A-3D, cathode terminals of the diodes can be connected to respective semiconductor die 105 and respective conductive terminals also using large gauge wire bonds 120. In some implementations, the large gauge wire bonds 120, which can be formed from aluminum bond wires, can be bonded first, followed by forming the small gauge wire bonds 118, which can be formed from gold wires or copper wires. Different wire bonding machines can be used for the two different types of bond wires, e.g., a wedge bonder for the aluminum bond wires and a ball bonder for the gold or copper bond wires. In some implementations, using a copper alloy bond wire can mitigate problems that can arise from the oxidation and/or hardness of copper, e.g., as compared with gold bond wires.

In some implementations, conductive clips (not shown) can be used in place of wire bonds for high current-carrying connections, e.g., in place of the large gauge wire bonds 120. Conductive clips can be more reliable than wire bonds, and easier to install. In some implementations, a soldering process or a sintering process (e.g., a same process used for semiconductor die attachment) can be used for clip attachment.

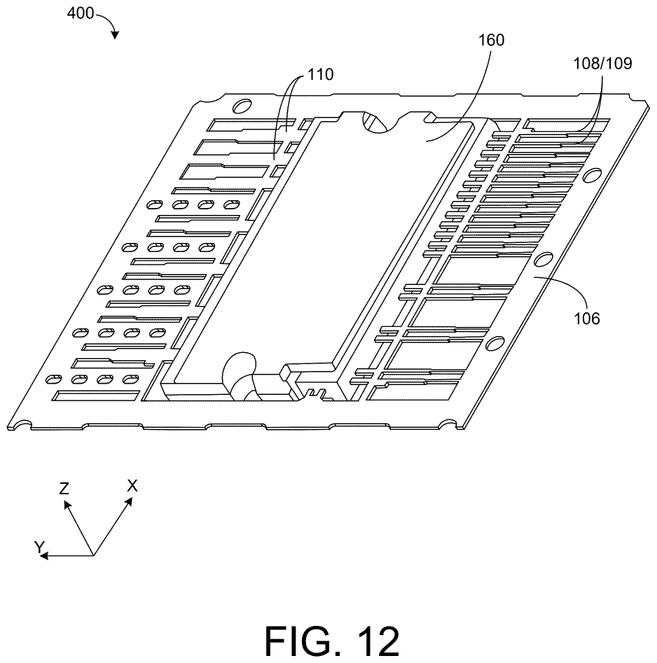

At operation 614, the method 600 includes an encapsulation operation can be performed to encapsulate, at least in part, components of the assembly 100 (or other assemblies described herein) in a molding compound 160, such as an epoxy molding compound applied using a transfer molding process, an injection molding process, or other encapsulation process. For example, as shown in FIG. 12, operation 614 can be used to produce the device package 400 (e.g., of FIGS. 4A to 4C).

In some implementations, the encapsulation of operation 614 can partially encapsulate a substrate of the assembly 100 (or other assemblies). For instance, a metal layer of the substrate for facilitating heat dissipation portions, such as the metal layer 102c, can be exposed through the molding compound 160, e.g., on an opposite side of the device package 400 shown in FIG. 12. A molding jig can be used to facilitate encapsulation of the device package 400, and to facilitate the metal layer being exposed after molding. At operation 614, the molding compound 160 can also partially encapsulate a leadframe of the assembly being produced, e.g., such that portions of the conductive terminals 108, portions of the conductive terminals 110, and one or more of the dambars 106 (tie bars, frame, etc.) are exposed outside the molding compound 160. In some implementations, the molding compound 160 can include a separate plastic housing that is included in a semiconductor device assembly.

In the example of FIG. 12, the molding compound 160 formed at operation 614 encapsulates (e.g., fully encapsulates) other elements, e.g., of the assembly 100, such as the IC semiconductor die 104, the semiconductor die 105, the DAP 103, the small gauge wire bonds 118, and the large gauge wire bonds 120, as well as a surface of the substrate 102 including the patterned metal layer 102b. In some implementations, such those described herein, respective sloped potions 107 of the conductive terminals 108, 109 and/or 110 can be encapsulated in the molding compound 160, e.g., to provide for spacing of exposed portions of the conductive terminals from, e.g., a heat sink coupled with the device package 400, such as a spacing of the distance D shown in FIG. 4C.

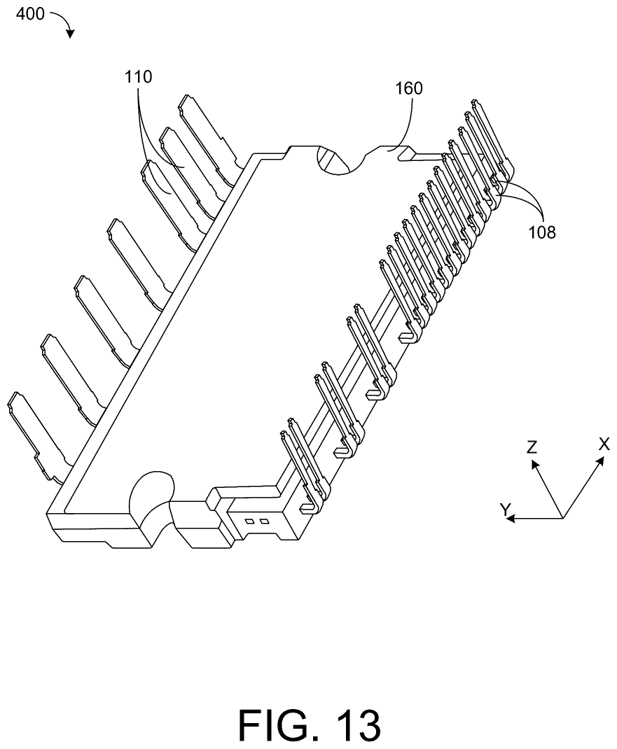

At operation 616, the method 600 includes trim and form operations. FIG. 13 illustrates the device package 400, after performing operation 614 on the structure shown in FIG. 12. In some implementations, a trim operation includes removing one or dambars (tie bars, frames, etc.), such as the dambar 106 shown in FIG. 12. The trim operation, in this example, is used to separate the conductive terminals 108, 109 and 110 from each other. In some implementations, the trim operation can be performed using a cutting die. In some implementations, prior to the trim operation, a plating operation (e.g., galvanic plating) can be performed to plate exposed (e.g., copper) portions of the conductive terminals with tin (Sn), which can prevent oxidation of the exposed portions of the conductive terminals and facilitate soldering of the conductive terminals to form electrical connections to external elements.

Also at operation 616 in the example method 600, after the trim operation, a forming operation is performed to bend the conductive terminals 108, 109 and 110 into their final configuration for the device package 400, such as in the arrangement shown in FIG. 13. In some implementations, the forming operation can include an initial pre-forming (bending) operation and a final forming (bending) operation. By splitting the forming operation into multiple steps, excess stress on the conductive terminals can be reduced or prevented, which can prevent damage to the conductive terminals, such as to the conductive terminals and/or the associated plating. In some implementations, the forming process can be carried out at a temperature of about 40 degrees C to prevent damage to copper surfaces and/or plating on those surfaces. Following operation 616, the device package 400 can undergo electrical (e.g., functional) testing.

In a general aspect, a semiconductor device assembly includes a substrate having a patterned metal layer, a first semiconductor die coupled with a first portion of the patterned metal layer, and a plurality of conductive terminals. At least one of the plurality of conductive terminals is coupled with a second portion of the patterned metal layer. The assembly further includes a die attach paddle coupled with a third portion of the patterned metal layer, and a second semiconductor die coupled with the die attach paddle. The assembly also includes a first bond wire electrically coupling the second semiconductor die with a first conductive terminal of the plurality of conductive terminals, a second bond wire electrically coupling the second semiconductor die with the die attach paddle, a third bond wire electrically coupling the second semiconductor die with the first semiconductor die, and a fourth bond wire electrically coupling the first semiconductor die with a second conductive terminal of the plurality of conductive terminals.

Implementations can include one or more of the following features or aspects, alone or in combination. For example, the assembly can include a third semiconductor die coupled with the first portion of the patterned metal layer.

The first semiconductor die can include a power transistor. The second semiconductor die can include a gate-drive control integrated circuit (IC). The third semiconductor die can include a diode.

The assembly can include a boot-strap device coupled with a respective conductive terminal of the plurality of conductive terminals. The boot-strap device can include a boot-strap resistor and a boot-strap diode. The boot-strap device can be configured to charge a power-supply terminal of the gate-drive control IC.

The first conductive terminal can be of a first gauge. The second conductive terminal can be of a second gauge larger than the first gauge.

The first bond wire, the second bond wire and the third bond wire can be of a first gauge. The fourth bond wire can be of a second gauge larger than the first gauge.

The first bond wire, the second bond wire and the third bond wire can be respective gold bond wires or respective copper bond wires. The fourth bond wire can be an aluminum bond wire.

The assembly can include a temperature sensing device coupled with the second portion of the patterned metal layer and the third portion of the patterned metal layer.

The patterned metal layer of the substrate can be a first metal layer disposed on a first side of the substrate. The substrate can include a second metal layer disposed on a second side of the substrate opposite the first side of the substrate. The semiconductor device assembly can include a molding compound that partially encapsulates the plurality of conductive terminals and partially encapsulates the substrate. The second metal layer of the substrate can be exposed through the molding compound. The molding compound can encapsulate the first semiconductor die, the die attach paddle, the second semiconductor die, the first bond wire, the second bond wire, the third bond wire and the fourth bond wire.

A first end of the first bond wire can be coupled with a surface of the first conductive terminal, and a second end of the first bond wire can be coupled with a surface of a bond pad of the second semiconductor die. The surface of the first conductive terminal can be vertically spaced from the surface of the bond pad by a distance in a range of 0.5 millimeters (mm) to 4 mm.

In another general aspect, a semiconductor device assembly includes a substrate having a first patterned metal layer including a first material, a second patterned metal layer including a second material different than the first material, a first semiconductor die coupled with a first portion of the first patterned metal layer, and a plurality of conductive terminals. At least one of the plurality of conductive terminals is coupled with a second portion of the first patterned metal layer. The assembly further includes a second semiconductor die coupled with the second patterned metal layer. the assembly also includes a first bond wire electrically coupling the second semiconductor die with a first conductive terminal of the plurality of conductive terminals, a second bond wire electrically coupling the second semiconductor die with the second patterned metal layer, a third bond wire electrically coupling the second semiconductor die with the first semiconductor die, and a fourth bond wire electrically coupling the first semiconductor die with a second conductive terminal of the plurality of conductive terminals.

Implementations can include one or more of the following features or aspects, alone or in combination. For example, the assembly can include a third semiconductor die coupled with the first portion of the first patterned metal layer.

The first semiconductor die can include a power transistor, the second semiconductor die can include a gate-drive control integrated circuit (IC), and the third semiconductor die can include a diode.

The assembly can include a boot-strap device coupled with a respective conductive terminal of the plurality of conductive terminals. The boot-strap device can include a boot-strap resistor, and a boot-strap diode. The boot-strap device can be configured to charge a power-supply terminal of the gate-drive control IC.

The first conductive terminal can be of a first gauge. The second conductive terminal can be of a second gauge larger than the first gauge.

The first bond wire, the second bond wire and the third bond wire can be of a first gauge. The fourth bond wire can be of a second gauge larger than the first gauge.

The first bond wire, the second bond wire and the third bond wire can be respective gold bond wires or respective copper bond wires. The fourth bond wire can be an aluminum bond wire.

The assembly can include a temperature sensing device coupled with the second portion of the first patterned metal layer and the second patterned metal layer.

The first patterned metal layer and the second patterned metal layer can be disposed on a first side of the substrate. The substrate can include a metal layer disposed on a second side of the substrate opposite the first side of the substrate. The assembly can include a molding compound that partially encapsulates the plurality of conductive terminals, and partially encapsulates the substrate. The metal layer disposed on the second side of the substrate can be exposed through the molding compound. The molding compound can encapsulate the first semiconductor die, the second semiconductor die, the first bond wire, the second bond wire, the third bond wire, and the fourth bond wire.

A first end of the first bond wire can be coupled with a surface of the first conductive terminal. A second end of the first bond wire can be coupled with a surface of a bond pad of the second semiconductor die. The surface of the first conductive terminal can be vertically spaced from the surface of the bond pad by a distance in a range of 0.5 millimeters (mm) to 4 mm.

A first end of the first bond wire can be coupled with a surface of the first conductive terminal. A second end of the first bond wire can be coupled with a surface of a bond pad of the second semiconductor die. The surface of the first conductive terminal can be coplanar with the surface of the bond pad.

The first material of the first patterned metal layer can include copper. The second material of the second patterned metal layer can include at least one of silver, gold; nickel gold; or nickel palladium gold.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. A semiconductor device assembly comprising:
a substrate having a patterned metal layer;
a first semiconductor die coupled with a first portion of the patterned metal layer;
a plurality of conductive terminals, at least one of the plurality of conductive terminals being coupled with a second portion of the patterned metal layer;
a die attach paddle coupled with a third portion of the patterned metal layer;
a second semiconductor die coupled with the die attach paddle;
a first bond wire electrically coupling the second semiconductor die with a first conductive terminal of the plurality of conductive terminals;
a second bond wire electrically coupling the second semiconductor die with the die attach paddle;
a third bond wire electrically coupling the second semiconductor die with the first semiconductor die; and
a fourth bond wire electrically coupling the first semiconductor die with a second conductive terminal of the plurality of conductive terminals.

2. The semiconductor device assembly of claim 1, further comprising a third semiconductor die coupled with the first portion of the patterned metal layer.

3. The semiconductor device assembly of claim 2, wherein:
the first semiconductor die includes a power transistor;
the second semiconductor die includes a gate-drive control integrated circuit (IC); and
the third semiconductor die includes a diode.

4. The semiconductor device assembly of claim 3, further comprising a boot-strap device coupled with a respective conductive terminal of the plurality of conductive terminals, the boot-strap device including:
a boot-strap resistor; and
a boot-strap diode,
the boot-strap device being configured to charge a power-supply terminal of the gate-drive control IC.

5. The semiconductor device assembly of claim 1, wherein:
the first conductive terminal is of a first gauge; and
the second conductive terminal is of a second gauge larger than the first gauge.

6. The semiconductor device assembly of claim 1, wherein:
the first bond wire, the second bond wire and the third bond wire are of a first gauge; and
the fourth bond wire is of a second gauge larger than the first gauge.

7. The semiconductor device assembly of claim 6, wherein:
the first bond wire, the second bond wire and the third bond wire are respective gold bond wires or respective copper bond wires; and
the fourth bond wire is an aluminum bond wire.

8. The semiconductor device assembly of claim 1, further comprising a temperature sensing device coupled with the second portion of the patterned metal layer and the third portion of the patterned metal layer.

9. The semiconductor device assembly of claim 1, wherein the patterned metal layer of the substrate is a first metal layer disposed on a first side of the substrate, the substrate further including a second metal layer disposed on a second side of the substrate opposite the first side of the substrate,
the semiconductor device assembly further comprising a molding compound that:
partially encapsulates the plurality of conductive terminals;
partially encapsulates the substrate, the second metal layer of the substrate being exposed through the molding compound; and
encapsulates the first semiconductor die, the die attach paddle, the second semiconductor die, the first bond wire, the second bond wire, the third bond wire and the fourth bond wire.

10. The semiconductor device assembly of claim 1, wherein:
a first end of the first bond wire is coupled with a surface of the first conductive terminal; and
a second end of the first bond wire is coupled with a surface of a bond pad of the second semiconductor die,
the surface of the first conductive terminal being vertically spaced from the surface of the bond pad by a distance in a range of 0.5 millimeters (mm) to 4 mm.

11. A semiconductor device assembly comprising:
a substrate having:
a first patterned metal layer including a first material; and
a second patterned metal layer including a second material different than the first material;
a first semiconductor die coupled with a first portion of the first patterned metal layer;
a plurality of conductive terminals, at least one of the plurality of conductive terminals being coupled with a second portion of the first patterned metal layer;
a second semiconductor die coupled with the second patterned metal layer;
a first bond wire electrically coupling the second semiconductor die with a first conductive terminal of the plurality of conductive terminals;
a second bond wire electrically coupling the second semiconductor die with the second patterned metal layer;
a third bond wire electrically coupling the second semiconductor die with the first semiconductor die; and
a fourth bond wire electrically coupling the first semiconductor die with a second conductive terminal of the plurality of conductive terminals.

12. The semiconductor device assembly of claim 11, further comprising a third semiconductor die coupled with the first portion of the first patterned metal layer.

13. The semiconductor device assembly of claim 12, wherein:
the first semiconductor die includes a power transistor;
the second semiconductor die includes a gate-drive control integrated circuit (IC); and
the third semiconductor die includes a diode.

14. The semiconductor device assembly of claim 13, further comprising a boot-strap device coupled with a respective conductive terminal of the plurality of conductive terminals, the boot-strap device including:
a boot-strap resistor; and
a boot-strap diode,
the boot-strap device being configured to charge a power-supply terminal of the gate-drive control IC.

15. The semiconductor device assembly of claim 11, wherein:
the first conductive terminal is of a first gauge; and
the second conductive terminal is of a second gauge larger than the first gauge.

16. The semiconductor device assembly of claim 11, wherein:
the first bond wire, the second bond wire and the third bond wire are of a first gauge; and
the fourth bond wire is of a second gauge larger than the first gauge.

17. The semiconductor device assembly of claim 16, wherein:
the first bond wire, the second bond wire and the third bond wire are respective gold bond wires or respective copper bond wires; and
the fourth bond wire is an aluminum bond wire.

18. The semiconductor device assembly of claim 11, further comprising a temperature sensing device coupled with the second portion of the first patterned metal layer and the second patterned metal layer.

19. The semiconductor device assembly of claim 11, wherein the first patterned metal layer and the second patterned metal layer are disposed on a first side of the substrate, the substrate further including a metal layer disposed on a second side of the substrate opposite the first side of the substrate,
the semiconductor device assembly further comprising a molding compound that:
partially encapsulates the plurality of conductive terminals;
partially encapsulates the substrate, the metal layer disposed on the second side of the substrate being exposed through the molding compound; and
encapsulates the first semiconductor die, the second semiconductor die, the first bond wire, the second bond wire, the third bond wire and the fourth bond wire.

20. The semiconductor device assembly of claim 11, wherein:
a first end of the first bond wire is coupled with a surface of the first conductive terminal; and
a second end of the first bond wire is coupled with a surface of a bond pad of the second semiconductor die,
the surface of the first conductive terminal being vertically spaced from the surface of the bond pad by a distance in a range of 0.5 millimeters (mm) to 4 mm.

21. The semiconductor device assembly of claim 11, wherein:
a first end of the first bond wire is coupled with a surface of the first conductive terminal; and
a second end of the first bond wire is coupled with a surface of a bond pad of the second semiconductor die,
the surface of the first conductive terminal being coplanar with the surface of the bond pad.

22. The semiconductor device assembly of claim 11, wherein:
the first material of the first patterned metal layer includes copper; and
the second material of the second patterned metal layer includes at least one of:
silver,
gold;
nickel gold; or
nickel palladium gold.
